(19) United States
(12) Patent Application Publication
(10) Pub. No.: US 2025/0357454 A1
(43) Pub. Date: Nov. 20, 2025

(54) Power Semiconductor Device Stack, Power Module, and Method of Producing a Power Semiconductor Device Stack

(71) Applicant: Infineon Technologies AG, Neubiberg (DE)

(72) Inventors: Anton Mauder, Kolbermoor (DE); Andrea Piccioni, Villach (AT); Hans-Joachim Schulze, Taufkirchen (DE); Edward Fürgut, Dasing (DE)

(21) Appl. No.: 19/194,237

(22) Filed: Apr. 30, 2025

(30) Foreign Application Priority Data
May 17, 2024 (DE) 102024204641.8

(51) Int. Cl. H01L 25/18; G01R 31/52; H01L 21/48; H01L 23/00; H01L 23/367; H02H 1/00; H02H 3/16; H10D 80/20

(52) U.S. Cl. CPC H01L 25/18; G01R 31/52; H01L 21/4875; H01L 23/3677; H01L 24/37; H01L 24/40; H01L 24/94; H01L 24/97; H02H 1/0007; H02H 3/16; H10D 80/231; H10D 80/251; H01L 24/32; H01L 24/48; H01L 24/73; H01L 2224/32145; H01L 2224/32245; H01L 2224/37013; H01L 2224/40145; H01L 2224/48137; H01L 2224/48245; H01L 2224/73263; H01L 2224/94; H01L 2224/97; H01L 2225/06589; H01L 2924/10253; H01L 2924/12036; H01L 2924/13091

(57) ABSTRACT

A stack includes a first power semiconductor device in a first chip and a second power semiconductor device in a second chip. The first power semiconductor device is configured for active operation during which an application load current is conducted by the first power semiconductor device and power losses occur in the first power semiconductor device. The second power semiconductor device is configured for passive operation during which a voltage is blocked. The stack further includes a heat sink interface configured to dissipate the power losses. The second chip is arranged between the first chip and the heat sink interface.

### TECHNICAL FIELD

This specification refers to embodiments of a power semiconductor device stack, to embodiments of a method of producing a power semiconductor device stack, and to embodiments of power module. The power semiconductor device stack may exhibit specific kind of coupling between a first power semiconductor device and a heat sink interface.

### BACKGROUND

Many functions of modern devices in automotive, consumer and industrial applications, such as converting electrical energy and driving an electric motor or an electric machine, rely on power semiconductor devices. For example, Insulated Gate Bipolar Transistors (IGBTs), Metal Oxide Semiconductor Field Effect Transistors (MOSFETs) and diodes, to name a few, have been used for various applications including, but not limited to switches in power supplies and power converters.

A power semiconductor device comprises a semiconductor body configured to conduct a forward load current along a load current path between two load terminals of the device. The load current is conducted by means of an active region of the power semiconductor device. The active region is surrounded by an edge termination region, which is terminated by an edge of the chip.

In case of a controllable power semiconductor device, e.g., a transistor, the load current path may be controlled by means of insulated electrodes, commonly referred to as gate electrodes. For example, upon receiving a corresponding control signal, e.g., from a driver unit and via a control terminal of the device, the control electrodes may set the power semiconductor device in one of a forward conducting state and a blocking state.

A general problem associated with power semiconductor device is the dissipation of heat caused during operation of the power semiconductor device, e.g., during switching processes and during conduction states. To dissipate the heat, a device typically referred to as heat sink can be thermally coupled to the power semiconductor device.

Moreover, more than one power semiconductor switches on different voltages can be used within an application, such that each of these devices requires an electrical insulation when coupled to the same heat sink in order to prevent short circuits. However, thick electrical isolators providing the required electrical insulation may have poor thermal conductivity.

The present disclosure is related to the coupling between a power semiconductor device and a heat sink.

### SUMMARY

According to an embodiment, a stack comprises: a first power semiconductor device in a first chip, wherein the first power semiconductor device is configured for active operation during which an application load current is conducted by the first power semiconductor device and power losses occur in the first power semiconductor device; a second power semiconductor device in a second chip, wherein the second power semiconductor device is configured for passive operation during which a voltage is blocked; and a heat sink interface for dissipating said power losses, wherein the second chip is arranged between the first chip and the heat sink interface.

According to another embodiment, a method of producing a stack comprises: providing a first power semiconductor device in a first chip, wherein the first power semiconductor device is configured for active operation during which an application load current is conducted by the first power semiconductor device and power losses occur in the first power semiconductor device; providing a second power semiconductor device in a second chip, wherein the second power semiconductor device is configured for passive operation during which a voltage is blocked; providing a heat sink interface for dissipating said power losses; and arranging the second chip between the first chip and the heat sink interface.

Those skilled in the art will recognize additional features and advantages upon reading the following detailed description, and upon viewing the accompanying drawings.

### BRIEF DESCRIPTION OF THE DRAWINGS

The parts in the figures are not necessarily to scale, instead emphasis is being placed upon illustrating principles of the invention. Moreover, in the figures, like reference numerals designate corresponding parts. In the drawings:

FIGS. 1 to 5 schematically and exemplarily illustrate a respective vertical cross-section of a section of a stack in accordance with some embodiments;

FIGS. 6 and 7 schematically and exemplarily illustrate a respective circuit diagram in accordance with some embodiments;

FIGS. 8 to 15 schematically and exemplarily illustrate a respective vertical cross-section of a section of a stack in accordance with some embodiments;

FIGS. 16 to 18 schematically and exemplarily illustrate a respective module comprising a stack in accordance with some embodiments; and

FIG. 19 schematically and exemplarily illustrates a perspective view of a wafer stack in accordance with one or more embodiments.

### DETAILED DESCRIPTION

In the following detailed description, reference is made to the accompanying drawings which form a part hereof and in which are shown by way of illustration specific embodiments in which the invention may be practiced.

In this regard, directional terminology, such as “top”, “bottom”, “below”, “front”, “behind”, “back”, “leading”, “trailing”, “above” etc., may be used with reference to the orientation of the figures being described. Because parts of embodiments can be positioned in a number of different orientations, the directional terminology is used for purposes of illustration and is in no way limiting. It is to be understood that other embodiments may be utilized and structural or logical changes may be made without departing from the scope of the present invention. The following detailed description, therefore, is not to be taken in a limiting sense, and the scope of the present invention is defined by the appended claims.

Reference will now be made in detail to various embodiments, one or more examples of which are illustrated in the figures. Each example is provided by way of explanation, and is not meant as a limitation of the invention. For example, features illustrated or described as part of one embodiment can be used on or in conjunction with other embodiments to yield yet a further embodiment. It is intended that the present invention includes such modifications and variations. The examples are described using specific language which should not be construed as limiting the scope of the appended claims. The drawings are not scaled and are for illustrative purposes only. For clarity, the same elements or manufacturing steps have been designated by the same references in the different drawings if not stated otherwise.

The term “horizontal” as used in this specification intends to describe an orientation substantially parallel to a horizontal surface of a semiconductor substrate or of a semiconductor structure. This can be for instance the surface of a semiconductor wafer or a die or a chip. For example, both the first lateral direction X and the second lateral direction Y mentioned below can be horizontal directions, wherein the first lateral direction X and the second lateral direction Y may be perpendicular to each other.

The term “vertical” as used in this specification intends to describe an orientation which is substantially arranged perpendicular to the horizontal surface, i.e., parallel to the normal direction of the surface of the semiconductor wafer/chip/die. For example, the extension direction Z mentioned below may be an extension direction that is perpendicular to both the first lateral direction X and the second lateral direction Y. The extension direction Z is also referred to as “first blocking direction Z” herein.

In this specification, n-doped is referred to as “first conductivity type” while p-doped is referred to as “second conductivity type”. Alternatively, opposite doping relations can be employed so that the first conductivity type can be p-doped and the second conductivity type can be n-doped.

In the context of the present specification, the terms “in ohmic contact”, “in electric contact”, “in ohmic connection”, and “electrically connected” intend to describe that there is a low ohmic electric connection or low ohmic current path between two regions, sections, zones, portions or parts of a semiconductor device or between different terminals of one or more devices or between a terminal or a metallization or an electrode and a portion or part of a semiconductor device, wherein “low ohmic” may mean that the characteristics of the respective contact are essentially not influenced by the ohmic resistance. Further, in the context of the present specification, the term “in contact” intends to describe that there is a direct physical connection between two elements of the respective semiconductor device; e.g., a transition between two elements being in contact with each other may not include a further intermediate element or the like.

In addition, in the context of the present specification, the term “electric insulation” is used, if not stated otherwise, in the context of its general valid understanding and thus intends to describe that two or more components are positioned separately from each other and that there is no ohmic connection connecting those components. However, components being electrically insulated from each other may nevertheless be coupled to each other, for example mechanically coupled and/or capacitively coupled and/or inductively coupled and/or electrostatically coupled (for example, in case of a junction). To give an example, two electrodes of a capacitor may be electrically insulated from each other and, at the same time, mechanically and capacitively coupled to each other, e.g., by means of an insulation, e.g., a dielectric.

Specific embodiments described in this specification pertain to, without being limited thereto, a power semiconductor device that may be used within a power converter or a power supply. Thus, in an embodiment, such power semiconductor device can be configured to carry a load current that is to be fed to a load and/or, respectively, that is provided by a power source. For example, the power semiconductor device may comprise one or more active power semiconductor unit cells, such as a monolithically integrated diode cell, a derivative of a monolithically integrated diode cell, a monolithically integrated transistor cell, e.g., a monolithically integrated IGBT or MOSFET cell and/or derivatives thereof. Such diode/transistor cells may be integrated within a single chip. A plurality of such cells may constitute a cell field that is arranged within an active region of the power semiconductor device.

The term “blocking state” of the power semiconductor device may refer to conditions, when the power semiconductor is in a state configured for blocking a load current flow while an external voltage is applied. More particularly, the power semiconductor device may be configured for blocking a forward load current through the power semiconductor device while a forward voltage bias is applied. In comparison, the power semiconductor device may be configured for conducting the forward load current in a “conducting state” of the power semiconductor device while a forward voltage bias is applied. A transition between the blocking state and the conducting state may be controlled by a control electrode or, more particularly, a potential of the control electrode. Said electrical characteristics may, of course, only apply within a predetermined working range of the external voltage and the current density within the power semiconductor device. The term “forward biased blocking state” therefore may refer to conditions with the power semiconductor device being in the blocking state while a forward voltage bias is applied.

The term “power semiconductor device” as used in this specification intends to describe a power semiconductor device on a single chip with high voltage blocking and/or high current-carrying capabilities. In other words, such power semiconductor device is intended for high current, typically in the Ampere range, e.g., up to several ten or hundred Ampere, and/or high voltages, typically above 15 V, more typically 100 V and above, e.g., up to at least 600 V or even more, e.g., up to at least 1.2 kV, or even up to 6 kV or more, depending on the respective application.

For example, the term “power semiconductor device” as used in this specification is not directed to logic semiconductor devices that are used for, e.g., storing data, computing data and/or other types of semiconductor-based data processing.

For example, the power semiconductor devices described below may be a respective single semiconductor chip, e.g., exhibiting a stripe cell configuration (or a cellular/needle cell configuration) and can be configured to be employed as a power component in a low-, medium- and/or high voltage application.

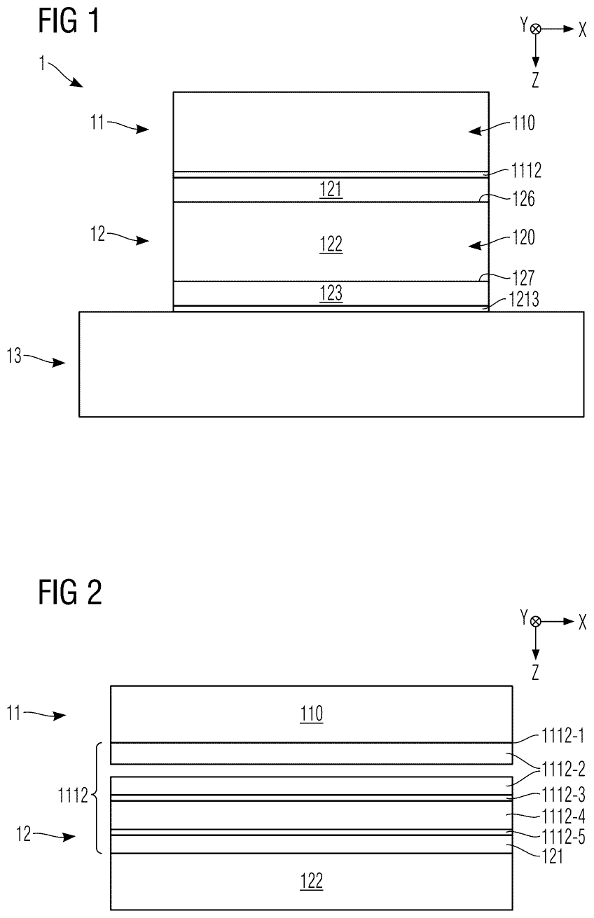

FIG. 1 schematically and exemplarily illustrates a vertical cross-section of a section of a stack in accordance with some embodiments.

The stack 1 comprises a first power semiconductor device 110 in a first chip 11. The first power semiconductor device 110 is configured for active operation during which an application load current is conducted by the first power semiconductor device 110 and power losses occur in the first power semiconductor device 110. The stack 1 further comprises a second power semiconductor device 120 in a second chip 12, wherein the second power semiconductor device 120 is configured for passive operation during which a voltage is blocked. The stack 13 further comprises a heat sink interface 13 for dissipating said power losses. The second chip 12 is arranged between the first chip 11 and the heat sink interface 13.

In accordance with some embodiments presented herein, it is proposed to use a stack of two semiconductor chips, e.g., thermally connected in series, one of which providing the electric isolation and thermal conductivity with respect to the heat sink interface. The electric isolation can for example be provided by a low-cost high voltage diode, e.g., based on silicon, which essentially has the task to isolate any high voltage potential at the bottom of the top switch from the heat sink interface while providing good thermal connection. Such diode may have asymmetric or symmetric blocking capability.

Referring to FIG. 1 again, in an embodiment, the second power semiconductor device 120 in the second chip 12 is configured to block a first blocking voltage along a first blocking direction Z pointing from a bottom of the first chip 11 to the heat sink interface 13.

In an embodiment, the second power semiconductor device 120 in the second chip 12 is further configured to block a second blocking voltage along a second blocking direction opposite to the first blocking direction Z.

In an embodiment, the second power semiconductor device 120 in the second chip 12 is configured to block said first blocking voltage up to a first maximum blocking voltage, and configured to block said second blocking voltage up to a second maximum blocking voltage, wherein the first maximum blocking voltage is different from the second maximum blocking voltage. For example, the ratio first maximum blocking voltage/second maximum blocking voltage is at least 5 or at least 10. Or, in another example, the ratio second maximum blocking voltage/first maximum blocking voltage is at least 5 or at least 10.

In an embodiment, the first power semiconductor device 110 in the first chip 11 exhibits a power transistor configuration.

In an embodiment, the second power semiconductor device 120 in the second chip 12 is based on silicon, Si. Further, the first power semiconductor device 110 in the first chip 11 is based on a wide band gap material, e.g., silicon carbide, SiC.

In an embodiment, the second power semiconductor device 120 in the second chip 12 exhibits a diode configuration having at least one pn-junction (cf. FIG. 9, reference numerals 126, 127).

For example, the second power semiconductor device 120 in the second chip 12 comprises a first doped region 121 of the first conductivity type coupled to the first power semiconductor device 110 in the first chip 11. Further, the second power semiconductor device 120 may comprise a substrate region 122 of the second conductivity type, wherein the substrate region 122 is coupled to the heat sink interface 13, optionally via a second doped region 123 of the first conductivity type or of the second conductivity type.

In an embodiment, the semiconductor body of the second device 120 does not include any further region having a dopant concentration higher than the dopant concentration of the first doped region 121 or higher than the dopant concentration of the substrate region 122 or higher than the dopant concentration of the second doped region 123 (if the second doped region 123 is provided). For example, the second device 120 comprises, at the back side where the second device 120 is coupled to the heat sink interface 13, no ohmic contact. For example, the second device 120 comprises, at the back side where the second device 120 is coupled to the heat sink interface 13, a Schottky contact.

In an embodiment, the second power semiconductor device 120 in the second chip 12 exhibits a non-punch-through configuration.

In an embodiment, the first chip 11 overlaps laterally with the second chip 12 entirely.

In an embodiment, the stack 1 comprises one or more other first chips 11 (cf., e.g., FIG. 13), each of which overlapping laterally with the second chip 12 entirely.

In an embodiment, the stack 1 comprises a metal-based interface layer 1112 between the first chip 11 and the second chip 12, wherein, e.g., cf. FIG. 2, the metal-based interface layer 1112 comprises one or more of the following: one or more layers 1112-1, 1112-5 based on Ti, TiN and/or Al; one or more layers 1112-2 based on NiSn and/or AuSn; one or more barrier layers 1112-3; one or more layers 1112-4 based on Cu; and/or one or more layers 1112-6 based on Ag.

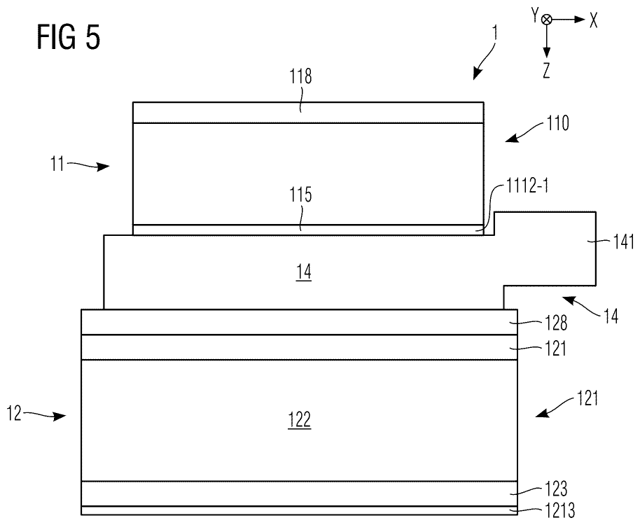

In an embodiment (cf. FIG. 5), the stack 1 further comprises an electrically conductive clip 14 between the first chip 11 and the second chip 12, wherein the clip 14 comprises a protruding portion 141 that does not laterally overlap with the first chip 11.

In an embodiment, the stack 1 further comprises a die attachment interface 1213 between the second chip 12 and the heat sink interface 13.

These and other aspects will be described in more detail below:

Still referring to FIG. 1, the first device 110 is for example a wide bandgap switch. For example, the first device 110 carries, during active operation, the application load current. During the active operation, which may include switching processes, e.g. at switching frequencies in the range of 1 kHz to 500 kHz, power losses occur within the first device 110, such as switching losses and conduction losses. These power losses cause the first device 110 to heat up. Accordingly, the first device 110 is coupled to the heat sink interface 13 via said second device 120, which is for example a high voltage Si diode in blocking mode, and which acts a) as electrical insulator between the first device 110 and the heat sink interface 13 and b) as thermal conductor to transfer heat from the first device 110 to the heat sink interface 13.

In an embodiment, the second device 120 does not carry the application load current or a portion thereof. Rather, the second device 120 only acts as a thermally conductive and electrically insulating coupling to the heatsink interface.

For example, said first doped region 121 of the second device 120 is an n-type cathode coupled to a back side of the first device 110.

The heat sink interface 13 can be configured in various ways depending on the application. For example, the heat sink interface 13 comprises a lead frame structure and/or a base plate. Further, the heat sink interface 13 is, in an embodiment, coupled to an active or a passive heat sink, such as an air cooler and/or a liquid cooler. The present disclosure is not limited to any specific heat sink configuration.

FIG. 2 illustrates an exemplary configuration of the metal-based interface layer 1112 that may be provided between the first chip 11 and the second chip 12. For example, this layer 1112 is arranged between the back side of the first device 110 and the first doped region 121 of the second device 120.

An interface to the back side of the first device 110 may be established with a layer based on Ti (cf. reference numeral 1112-1). Likewise, an interface to the first doped region 121 of the second device 120 may also be established with a layer based on Ti, TiN and/or Al (cf. reference numeral 1112-5). Coupled to the layer 1112-1, one or more layers 1112-2 based on NiSn and/or AuSn, e.g., acting as contact layer(s) may be provided. Optionally, one or more barrier layers 1112-3 and/or one or more layers 1112-4 based on copper, Cu, may be provided between said layers 1112-1 and 1112-5, e.g., to increase a lateral electrical conductivity and/or a thermal capacitance of the metal-based interface layer 1112. In general, the interface to the back side of the first device 110 may be based on any die attach technology, e.g. diffusion soldering, sintering, soft soldering, thermal conductive glue, hybrid sintering. For example, the material used therein can be any metal, e.g., Sn, Ni, Au, Ag, Cu, etc. The exact configuration of the metal-based interface layer 1112 may depend on the characteristics of the devices 11 and 12 to be coupled with each other.

The thicknesses of the layers mentioned above may be within the following ranges:
layer 1112-1 based on Ti: 0.05 μm . . . to 0.5 μm . . .
layer 1112-2 based on NiSn and/or AuSn: 0.1 μm . . . to 5 μm . . .
barrier layer 1112-3: 0.01 μm . . . to 0.1 μm . . .
Cu layer 1112-4: 1 μm . . . to 1500 μm . . .
layer 1112-5 based on Ti, TiN and/or Al: 0.05 . . . to 10 μm . . .

In accordance with an embodiment, the contact/attach to the devices 110 and 120 is provided by diffusion soldering, e.g., of NiSn with the total thickness of NiSn larger than the short-ranging thickness variations of the stack 1 (e.g., in the range of 1 . . . 3 μm, cf. layer(s) 1112-2). Should a high lateral electric conductivity be needed at the interface devices 110 and 120, an enhancing layer (e.g., said Cu layer 1112-4) can be provided, e.g., to the front of the second device 120. For example, due to a low temperature budget (e.g. smaller than 400° C. for short times), requirements with regards to a barrier (cf. layer 1112-5, e.g., based on Ti, TiN and/or Al) to the second device 120 may be reduced.

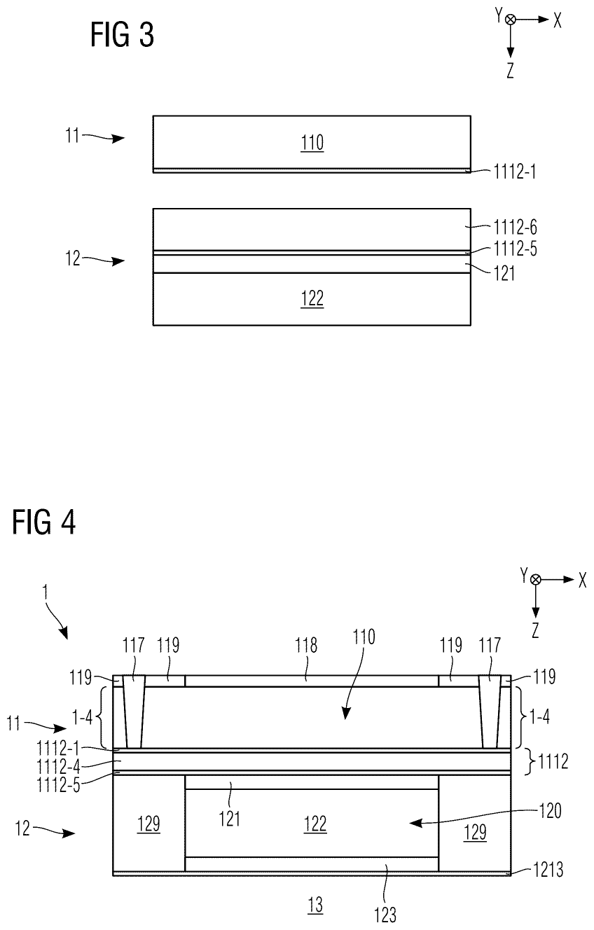

FIG. 3 illustrates another exemplary configuration of the metal-based interface layer 1112 that may be provided between the first chip 11 and the second chip 12. For example, this layer 1112 is coupled to the back side of the first device 110 and to the first doped region 121 of the second device 120. As in the first example according to FIG. 2, an interface to the back side of the first device 110 may be established with a layer based on Ti (cf. reference numeral 1112-1). Likewise, an interface to the first doped region 121 of the second device 120 may also be established with a layer based on Ti, TiN and/or Al (cf. reference numeral 1112-5). Coupled to the layer 1112-5, there may be arranged a layer 1112-6 based on Ag, e.g., an Ag sinter layer. Such Ag sinter layer may be beneficial with regards to a wafer bonding processing step, e.g., when the first device 11, equipped with layer 1112-1, is bonded to the second device 12, equipped with said layers 1112-5 and 1112-6. The Ag based layer 1112-6 may be produced by employing a low-pressure sintering processing step using Ag nano particles, for example, or by a conventional Ag sintering processing step.

FIG. 4 illustrates a further embodiment of the stack 1. In this embodiment, the first device 110 and the second device 120 are coupled to each other based on the metal-based interface layer 1112, e.g., including said Cu layer 1112-4 and the layers 1112-1, 1112-5 based on Ti, TiN and/or Al, wherein it shall be understood that this configuration of the metal-based interface layer 1112 is only exemplary.

The second chip 12 includes the second device 120 surround by an edge structure 129. Both the second device 120 and the edge structure 129 are arranged above conductive layer 1213, which may be coupled to the heat sink interface 13.

The first chip 11 houses the first device 110 and optionally provided vias 117. For example, these edge vias may be provided to electrically contact the back side terminal of the first device 110, if present. The first device 110 can for example exhibit a vertical configuration, according to which said application load current flows along a direction in parallel to the first blocking direction Z in the first device 110, namely between a first load terminal at the front side and a second load terminal at the back side. To contact said second load terminal, said vias 117 may be provided. If, however, the first device 110 exhibits a lateral configuration, both the first load terminal and the second load terminal are arranged at the front side of the first device 110 and it may accordingly not be necessary to electrically contact the back side from the front side of the first chip 11. If the vias 117 are provided, these may be arranged in the edge termination region of the first device 110, e.g., close to the edge 1-4 of the first chip 11. On top of the first chip 11, there may be provided an insulation layer 119 and a front side metallization 118, e.g., for forming the first load terminal of the first device 110.

A further variant of the coupling between the two chips 11 and 12 is illustrated in FIG. 5. According to this embodiment, said electrically conductive clip 14 is arranged between the first chip 11 and the second chip 12, wherein the clip 14 comprises said protruding portion 141 that does not laterally overlap with the first chip 11. For example, the clip 14 is coupled to a back side metallization 115 of the first device 110 (e.g., forming said second load terminal at the back side of the first device 110) and to a front side metallization 128 of the second device 120. Based on the protruding portion 141, the back side metallization 115 of the first device 110 may be electrically contacted and, for example, said vias 117 may be omitted. For example, the clip 14 is first attached to the front side metallization 128 of the second device 120 before the first chip 11 is mounted. Interfaces between said clip 14 and the back side metallization 115 of the first device or the front side metallization 128 of the second device 120 may be realized by the same or different methods, e.g., soft soldering, diffusion soldering, sintering or glueing.

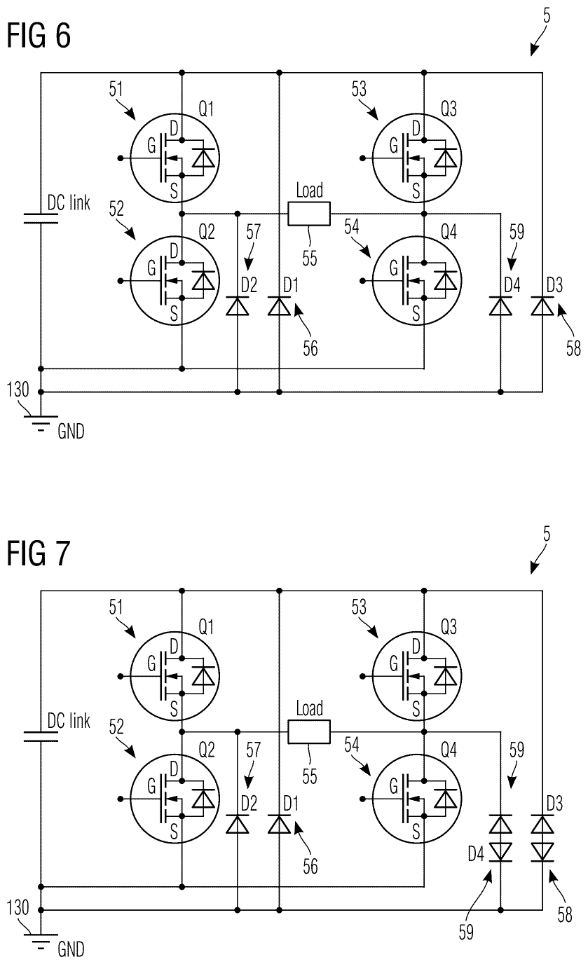

FIG. 6 illustrates an application of the above-described stacks 1. According to the example illustrated in FIG. 6, four transistors 51, 52, 53 and 54, e.g., SiC based MOSFETs Q1 to Q4, form a full bridge circuit 5 coupled to a DC link and a load. Each of the MOSFETs Q1 to Q4 comprises a source terminal S, a drain terminal D and a gate terminal G, and each of the MOSFETs Q1 to Q4 forms a respective first device 110 as described above. Four diodes 56, 57, 58 and 59 (D1 to D4) are additionally provided. Each of the diodes D1 to D4 forms a respective second device 120 as described above. The diode D1 is coupled to the drain terminal D of MOSFET Q1, forming a stack 1 as described above. The diode D2 is coupled to the drain terminal D of MOSFET Q2, thereby forming a further stack 1 as described above. The diode D3 is coupled to the drain terminal D of MOSFET Q3, thereby forming a further stack 1 as described above. The diode D4 is coupled to the drain terminal D of MOSFET Q4, thereby forming a yet further stack 1 as described above. Via the respective heat sink interfaces 13, e.g., via the back sides of the diodes D1 to D4, the diodes D1 to D4 are coupled to protecting earth/ground GND, e.g., a grounded heat sink 130.

The example illustrated in FIG. 7 essentially corresponds to the example of FIG. 6, such that is referred to the above. However, according to the example illustrated in FIG. 7, the four diodes D1 to D4 which form the respective second devices 120 each exhibit the above-described bi-directional blocking capabilities, according to which said first blocking voltage can be blocked along the first blocking direction said second blocking voltage can be blocked along a second blocking direction opposite to the first blocking direction. For example, when one of the MOSFETS Q2 and Q4 is in a body diode operation, the current source characteristic of the load may require its drain potential to be more negative than its source potential. Since the source terminals S of the MOSFETS Q2 and Q4 are electrically connected to ground GND (and, accordingly, the source potential is on ground potential), the drain potential has to become negative. The diodes D2 and D4 in this case may see a small voltage drop (e.g., in case of SiC based MOSFETs, within the range of 2 to 4 V), which would render a standard Si-based pn-diode into conduction mode. To avoid this, the diodes D3 and D4 are configured with reverse blocking capability. As described above, an asymmetric blocking capability can be sufficient. For example, the first maximum blocking voltage is greater than 1000 V, and the second maximum blocking voltage can be in range of 10 V.

The circuit arrangements shown in FIGS. 6 and 7 are only for illustrative purposes and not intended to be limiting. Alternatively, there may be an additional half bridge configuration formed by two additional transistors each with a corresponding diode forming the second device 120. In a further alternative embodiment, the circuit arrangement may consist only of one half bridge (e. g. only two transistors 51, 52, e. g. MOSFETs Q1 and Q2 with their corresponding diodes D1 and D2 which form the second devices 120. In a further alternative embodiment, the circuit arrangement may consist of only one transistor 51 or 52, e. g. MOSFETs Q1 or Q2 either as high side or low side device with the corresponding diode D1 or D2. The respective other transistor may be missing or may be replaced by a free wheeling device, e. g. a bipolar diode or a Schottky barrier diode. In a further alternative, the free wheeling device may be arranged on a corresponding second device 120.

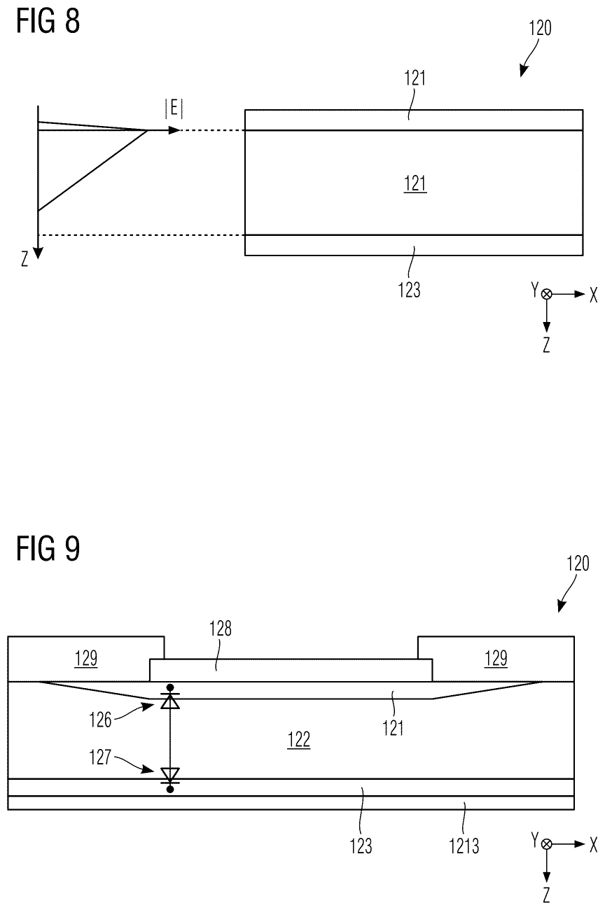

FIG. 8 illustrates an exemplary course of the electric field |E| in the second device 120. As explained above, the primary function of the second device 120 is to act as an electrical insulator (i.e., blocking a voltage) and as thermal conductor. This allows for a simple design of the second device 120, e.g., a simple diode design exhibiting a non-punch through characteristic, as illustrated in FIG. 8 (where the electrical field terminates within the substrate region 122). For example, an additional field stop layer need not necessarily be provided for the second device 120.

FIG. 9 illustrates a further embodiment of the second device 120. According to this embodiment, the second device 120 is a bidirectionally blocking diode, wherein the substrate region 122 is based on a low p-doped material. At the front side, the first doped region 121 establishes a first cathode, which e.g. is formed by implantation of donors, and an annealing may form the first pn-junction 126 (J1). Further, below the edge structure 129 (e.g., a passivation layer), a non-illustrated planar high voltage edge termination may be provided in the edge region, e.g., including a variation of the lateral doping (VLD) structure, a junction termination extension (JTE) structure, one or more field rings, and/or one or more field plates. On the back side, the optional second doped region 123 establishes a second cathode. Since the corresponding second pn-junction 127 (J2) only needs to block little more than the forward voltage of the body diode, dedicated edge termination patterns can be avoided at the back side of the second device 120.

In an embodiment, when applying the same voltage level lower than the lower value of the first and second maximum blocking voltage as a first blocking voltage to the first pn-junction 126 and as a second blocking voltage to the second pn-junction 127, a first leakage current being caused at the first pn-junction 126 may be lower than a second leakage current caused at the second pn-junction 128 at least by a factor of 10.

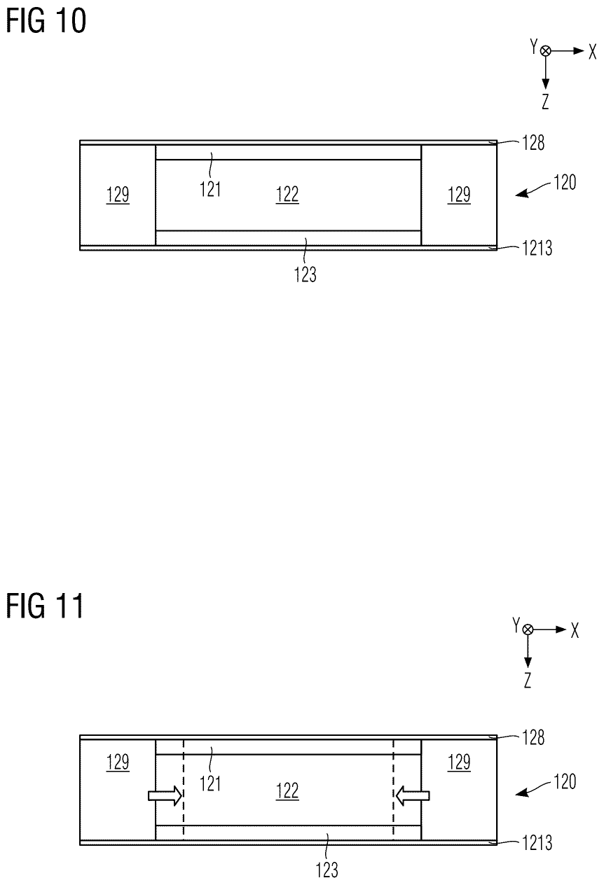

FIGS. 10 and 11 illustrate a yet further embodiment of the second device 120. There, as according to FIG. 4, the edge structure 129 extends from the front side to the back side of the second device 120. For example, the edge structure 129 is in this embodiment based on zinc-borate-(B—Zn—) glass or on borosilicate glass. As indicated based on the vertical dashed lines in FIG. 11, by dimensioning the lateral width of the edge structure 129, the cooling effect with respect to the peripheral region of the first device 110 can be influenced. For example, depending on the material of the edge structure 129, the thermal conductivity of the edge structure 129 can be comparatively low, implying that the peripheral region of the first chip 11 laterally overlapping with the edge structure 129 of the second chip 12 is cooled less effectively as compared to the portion of the first chip 11 laterally overlapping with the substrate region 122. However, typically, the central region of the first chip 11 becomes, during active operation, hotter as compared to the peripheral region. Accordingly, based on the dimensioning of the lateral width of the edge structure 129, such potential temperature gradient in the first device 110 can be reduced or even avoided. Accordingly, in an embodiment, the edge structure 129 of the second chip 12 may laterally overlap with a peripheral portion of an active region of the first device 110.

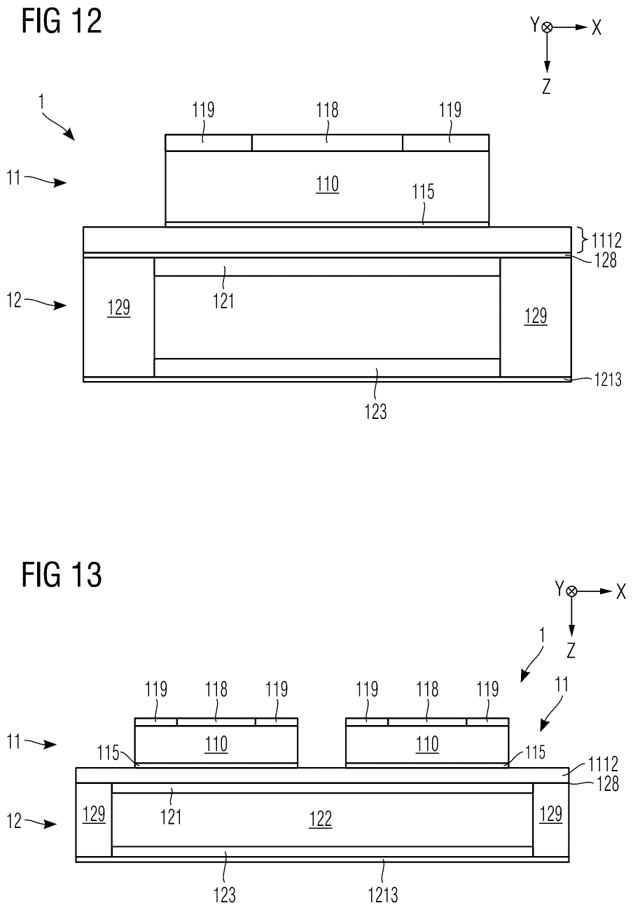

FIG. 12 illustrates a further embodiment of the stack 1. Accordingly, the horizontal cross-sectional area of the first chip 11 may be smaller than the horizontal cross-sectional area of the second chip 12. Similar to the variant of FIG. 5, such design may allow a simple electrical connection to the second load terminal of the first device 110, if the same exhibits a vertical configuration according to which the second load terminal is implemented as said back side metallization 115. For example, as illustrated, also the horizontal cross-sectional area of the metal-based interface layer 1112 (e.g., in this embodiment consisting of only the Cu based layer 1112-4) may also be greater than the horizontal cross-sectional area of the first chip 11, e.g., identical to the horizontal cross-sectional area of the second chip 12. To electrically contact the back side metallization 115 of the first device 110, portions of the metal-based interface layer 1112 not covered by the first chip 11 can be contacted, in accordance with an embodiment.

Yet further embodiments of the stack 1 are illustrated in FIGS. 13 to 15. In accordance with these embodiments, the horizontal cross-sectional area of the first chip 11 is significantly smaller than the horizontal cross-sectional area of the second chip 1, e.g., such that several first chips 11 may be arranged on top of the metal-based interface layer 1112 (e.g., in these embodiments consisting of only the Cu based layer 1112-4 or the clip 14). Depending on the application, the second load terminals of the first devices 110 can be implemented as a respective back side metallization 115 which can be short-circuited with each other metal-based interface layer 1112, cf. FIG. 13. Such configuration may be beneficial for connecting the first devices 110 in parallel with each other.

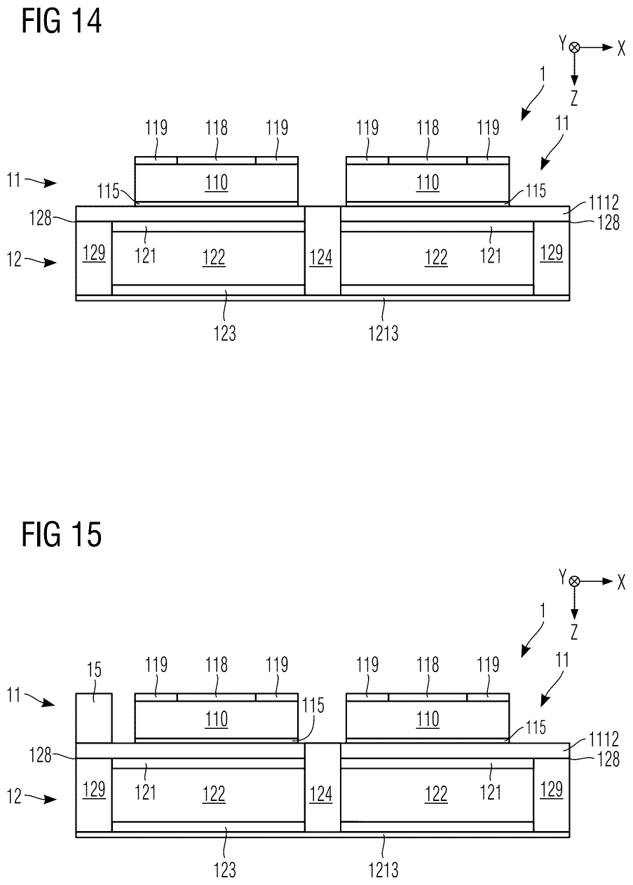

In case such short-circuit between the second load terminals of the first devices 110 shall not be established, a further insulation structure 124 configured similar as the edge structures 129 may be provided, as illustrated in FIGS. 14 and 15, so as to electrically isolate the second load terminals of the first devices 110 from each other. Such configuration may be beneficial for connecting the first devices 110 in a half bridge topology. The edge structures may be formed by vertical edge structures described in FIGS. 10 and 11 but also may be formed by planar edge structures as described in FIG. 9.

Moreover, as illustrated in FIG. 15, a further component 15 may be mounted on a portion of the metal-based interface layer 1112 not covered by the at least one first chip 11. For example, the further component is or includes a level shifter, a logic circuit, a sensor (e.g., temperature sensor), and/or a gate driver.

Presented herein is also a module 3 comprising a stack 1, e.g., exhibiting one of the above-described configurations.

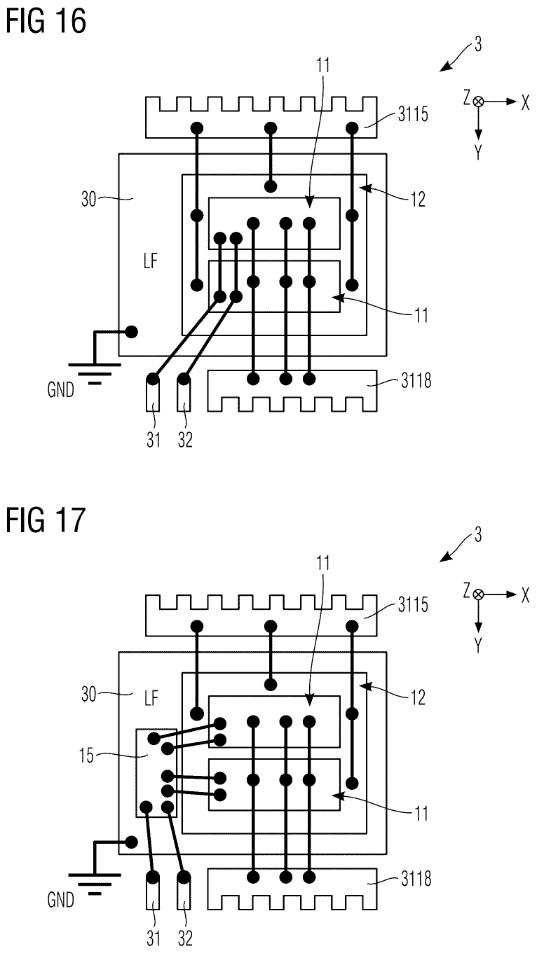

For example, referring to FIGS. 16 and 17, the module 3 has two first chips 11 mounted on one second chip 12 within a package structure 30 having a lead frame, LF, component, wherein the LF component may be connected to ground GND.

A drain connector structure 3115 of the module 3 is electrically connected to the second chip 12, e.g., via bond wires as schematically illustrated in FIGS. 16-17, e.g., to the (non-illustrated) metal-based interface layer 1112, which may establish the electrical connection to both the first doped region 121 of the second device 120 and, e.g., the (non-illustrated) back side metallizations 115 of the first devices 110.

A source connector structure 3118 of the module 3 is electrically connected to the first chips 11, e.g., via bond wires as schematically illustrated in FIGS. 16-17, e.g., to the (non-illustrated) front side metallizations 118 of the first chips 11. Further connector structures 31 and 32 of the module 3 can be electrically connected to other portions of the first chips, e.g., gate terminals of the first chips 11 and/or sensor terminals of the first chips 11. Compared to the embodiment illustrated in FIG. 16, in the embodiment according to FIG. 17, the package structure 30 additionally houses the further component 15 (cf. FIG. 15), which can for example be a gate driver unit mounted on the LF component.

For example, the package structure 30 exhibits a surface-mount-device, SMD, configuration.

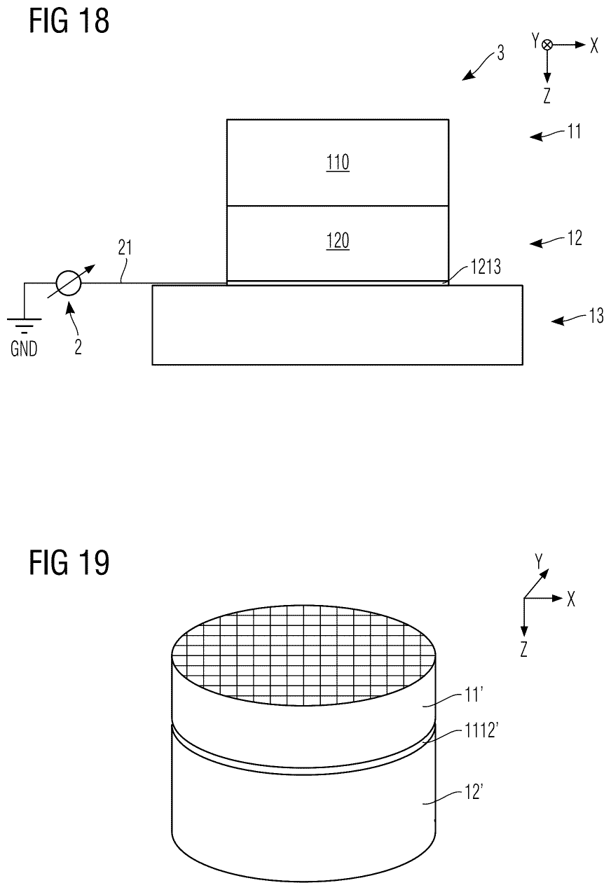

Referring to FIG. 18, in an embodiment, the module 3 further comprises a leakage current monitor 2, wherein the leakage current monitor 2 is configured to sense a leakage current at the second chip 12. For example, the leakage current monitor 2 is operatively coupled to the first power semiconductor device 110 in the first chip 11 to turn the first power semiconductor device 110 off in dependence of the leakage current.

For example, the leakage current can be detected by sensing the current at the die attachment interface 1213, e.g. by a wire or a tie bar connection 21. For example, an increased leakage current above a threshold may be detected and may trigger a safe turn-off of the first device 110. For example, monitoring of leakage current of a heat sink coupled to the heat sink interface 13 can be avoided.

Presented herein is also a method of producing a stack. For example, the method of producing the stack comprises: providing a first power semiconductor device in a first chip, wherein the first power semiconductor device is configured for active operation during which an application load current is conducted by the first power semiconductor device and power losses occur in the first power semiconductor device; providing a second power semiconductor device in a second chip, wherein the second power semiconductor device is configured for passive operation during which a voltage is blocked; providing a heat sink interface for dissipating said power losses; and arranging the second chip between the first chip and the heat sink interface.

Embodiments of the above-described methods correspond to the embodiments of the power semiconductor device 1 described above. Accordingly, these embodiments of the method will not literally be described herein, but it is referred to the above.

For example, referring to FIG. 19, coupling the first chip 11 to the second chip 12 is carried out based on a wafer bonding processing step, according to which a first wafer 11′ including a plurality of first chips 11 is bonded to a second wafer 12′ including a plurality of second chips 12. Subsequently, a wafer dicing processing step may be carried out to form a plurality of stacks 1. For example, before the wafer bonding processing step, both the plurality of first chips 11 in the first wafer 11′ and the plurality of second chips 12 in the second wafer 12′ have been completely processed.

For example, the wafer bonding is done with an interface layer 1112′, e.g., using diffusion or eutectic bonding with the bonding metals being deposited on both the front side of the second wafer 12′ and the back side of the first wafer 11′. For example, respectively said bonding is done by applying homogeneous pressure at typical die attach temperatures. After bonding, the wafer stack can be diced using conventional mechanic or laser dicing.

In the above, embodiments pertaining to power semiconductor devices and corresponding production methods were explained.

For example, these power semiconductor devices are based on silicon (Si). Accordingly, a monocrystalline semiconductor region or layer, e.g., the semiconductor body and its regions/zones, e.g., regions etc. can be a monocrystalline Si-region or Si-layer. In other embodiments, polycrystalline or amorphous silicon may be employed.

It should, however, be understood that these power semiconductor devices can be made of any semiconductor material suitable for manufacturing a semiconductor device, as specifically mentioned above. Examples of such materials include, without being limited thereto, elementary semiconductor materials such as silicon (Si) or germanium (Ge), group IV compound semiconductor materials such as silicon carbide (SiC) or silicon germanium (SiGe), binary, ternary or quaternary III-V semiconductor materials such as gallium nitride (GaN), gallium arsenide (GaAs), gallium phosphide (GaP), indium phosphide (InP), indium gallium phosphide (InGaPa), aluminum gallium nitride (AlGaN), aluminum indium nitride (AlInN), indium gallium nitride (InGaN), aluminum gallium indium nitride (AlGaInN) or indium gallium arsenide phosphide (InGaAsP), and binary or ternary II-VI semiconductor materials such as cadmium telluride (CdTe) and mercury cadmium telluride (HgCdTe) to name few. The aforementioned semiconductor materials are also referred to as “homojunction semiconductor materials”. When combining two different semiconductor materials a heterojunction semiconductor material is formed. Examples of heterojunction semiconductor materials include, without being limited thereto, aluminum gallium nitride (AlGaN)-aluminum gallium indium nitride (AlGaInN), indium gallium nitride (InGaN)-aluminum gallium indium nitride (AlGaInN), indium gallium nitride (InGaN)-gallium nitride (GaN), aluminum gallium nitride (AlGaN)-gallium nitride (GaN), indium gallium nitride (InGaN)-aluminum gallium nitride (AlGaN), silicon-silicon carbide (SixC1-x) and silicon-SiGe heterojunction semiconductor materials. For power semiconductor switches applications currently mainly Si, SiC, GaAs and GaN materials are used.

Spatially relative terms such as “under”, “below”, “lower”, “over”, “upper” and the like, are used for ease of description to explain the positioning of one element relative to a second element. These terms are intended to encompass different orientations of the respective device in addition to different orientations than those depicted in the figures. Further, terms such as “first”, “second”, and the like, are also used to describe various elements, regions, sections, etc. and are also not intended to be limiting. Like terms may refer to like elements throughout the description.

As used herein, the terms “having”, “containing”, “including”, “comprising” and the like are open ended terms that indicate the presence of stated elements or features, but do not preclude additional elements or features. The articles “a”, “an” and “the” are intended to include the plural as well as the singular, unless the context clearly indicates otherwise.

The expression “and/or” should be interpreted to cover all possible conjunctive and disjunctive combinations, unless expressly noted otherwise. For example, the expression “A and/or B” should be interpreted to mean A but not B, B but not A, or both A and B. The expression “at least one of” should be interpreted in the same manner as “and/or”, unless expressly noted otherwise. For example, the expression “at least one of A and B” should be interpreted to mean A but not B, B but not A, or both A and B.

Although specific embodiments have been illustrated and described herein, it will be appreciated by those of ordinary skill in the art that a variety of alternate and/or equivalent implementations may be substituted for the specific embodiments shown and described without departing from the scope of the present invention. This application is intended to cover any adaptations or variations of the specific embodiments discussed herein. Therefore, it is intended that this invention be limited only by the claims and the equivalents thereof.

What is claimed is:

1. A stack, comprising:
a first power semiconductor device in a first chip, wherein the first power semiconductor device is configured for active operation during which an application load current is conducted by the first power semiconductor device and power losses occur in the first power semiconductor device;
a second power semiconductor device in a second chip, wherein the second power semiconductor device is configured for passive operation during which a voltage is blocked; and
a heat sink interface configured to dissipate the power losses, wherein the second chip is arranged between the first chip and the heat sink interface.

2. The stack of claim 1, wherein the second power semiconductor device is configured to block a first blocking voltage along a first blocking direction pointing from a bottom of the first chip to the heat sink interface.

3. The stack of claim 2, wherein the second power semiconductor device is configured to block a second blocking voltage along a second blocking direction opposite to the first blocking direction.

4. The stack of claim 3, wherein the second power semiconductor device is configured to block the first blocking voltage up to a first maximum blocking voltage, and configured to block the second blocking voltage up to a second maximum blocking voltage, and wherein the first maximum blocking voltage is different from the second maximum blocking voltage.

5. The stack of claim 1, wherein the first power semiconductor device has a power transistor configuration.

6. The stack of claim 1, wherein the second power semiconductor device is based on Si, and/or wherein the first power semiconductor device is based on a wide band gap material.

7. The stack of claim 1, wherein the second power semiconductor device has a diode configuration having at least one pn-junction.

8. The stack of claim 7, wherein the second power semiconductor device comprises a first doped region of a first conductivity type coupled to the first power semiconductor device, and a substrate region of a second conductivity type, and wherein the substrate region is coupled to the heat sink interface.

9. The stack of claim 8, wherein the substrate region is coupled to the heat sink interface via a second doped region of the first conductivity type or of the second conductivity type.

10. The stack of claim 1, wherein the second power semiconductor device has a non-punch-through configuration.

11. The stack of claim 1, wherein the first chip overlaps laterally with the second chip entirely.

12. The stack of claim 1, further comprising one or more other first chips, each of which overlaps laterally with the second chip entirely.

13. The stack of claim 1, further comprising a metal-based interface layer between the first chip and the second chip.

14. The stack of claim 1, further comprising an electrically conductive clip between the first chip and the second chip, wherein the clip comprises a protruding portion that does not laterally overlap with the first chip.

15. The stack of claim 1, further comprising a die attachment interface between the second chip and the heat sink interface.

16. A module comprising the stack of claim 1.

17. The module of claim 16, further comprising a leakage current monitor configured to sense a leakage current at the second chip.

18. The module of claim 17, wherein the leakage current monitor is operatively coupled to the first power semiconductor device to turn the first power semiconductor device off in dependence of the leakage current.

19. A method of producing a stack, the method comprising:
providing a first power semiconductor device in a first chip, wherein the first power semiconductor device is configured for active operation during which an application load current is conducted by the first power semiconductor device and power losses occur in the first power semiconductor device;
providing a second power semiconductor device in a second chip, wherein the second power semiconductor device is configured for passive operation during which a voltage is blocked; and
arranging the second chip between the first chip and a heat sink interface, wherein the heat sink interface is configured to dissipate the power losses.

20. The method of claim 19, further comprising:
a wafer bonding processing step; and
a subsequent dicing processing step.
